(19) United States
(12) Patent Application Publication
(10) Pub. No.: US 2012/0153442 A1
(43) Pub. Date: Jun. 21, 2012

(54) SILICON NITRIDE FILM AND PROCESS FOR PRODUCTION THEREOF, COMPUTER-READABLE STORAGE MEDIUM, AND PLASMA CVD DEVICE

(75) Inventors: Minoru Honda, Amagasaki-shi (JP); Masayuki Kohno, Amagasaki-shi (JP)

(73) Assignee: TOKYO ELECTRON LIMITED, Tokyo (JP)

(21) Appl. No.: 13/164,337

(22) Filed: Jun. 20, 2011

Related U.S. Application Data
(63) Continuation-in-part of application No. 13/121,615, now abandoned.

(30) Foreign Application Priority Data
Sep. 30, 2008 (JP) 2008-253934

(51) Int. Cl. H01L 23/58; C23C 16/511; H01L 21/318

(52) U.S. Cl. 257/649; 438/792; 118/723 VE; 257/E23.002; 257/E21.293

(57) ABSTRACT

Provided is a process of forming a silicon nitride film having concentration of hydrogen atoms below or equal to 9.9×10²⁰ atoms/cm³ in the silicon nitride film by using a plasma CVD device, which generates plasma by introducing microwaves into a process chamber by using a planar antenna having a plurality of apertures, by setting the pressure inside a process chamber within a range from 0.1 Pa to 6.7 Pa and by performing a plasma CVD by using a raw material gas for film formation including SiCl₄ gas and nitrogen gas.

### CROSS-REFERENCE TO RELATED APPLICATION

This is a continuation-in-part application of U.S. application Ser. No. 13/121,615, filed on Mar. 29, 2011, which claims the benefit of Japanese Patent Application No. 2008-253934, filed on Sep. 30, 2008 in the Japan Patent Office, the disclosure of which is incorporated herein in its entirety by reference.

### TECHNICAL FIELD

The present invention relates to a silicon nitride film and a process for production thereof, a computer-readable storage medium used in the process, and a plasma CVD device.

### BACKGROUND ART

Currently, a thermal annealing method, a plasma nitrification method, etc. that perform a nitrification process on silicon are known as methods of forming a high quality silicon nitride film having high insulating properties. However, when a multilayer insulation film is formed, a nitrification process cannot be used, and the multilayer insulation film may be formed by depositing a silicon nitride film by using a CVD (Chemical Vapor Deposition) method. In order to form a silicon nitride film having high insulating properties by using a CVD method, formation of the silicon nitride film needs to be performed at a high temperature from 600° C. to 900° C. Thus, a device may be adversely affected due to increase of a thermal budget, and moreover, several restrictions may be generated while preparing the device.

Meanwhile, a plasma CVD method may be performed at a temperature around 500° C., but a charging damage may be generated due to plasma having a high electron temperature. Furthermore, although silane (SiH₄) or disilane (Si₂H₆) is generally used as a raw material for film formation in a plasma CVD method, a large amount of hydrogen originated from the raw materials is included in a silicon nitride film formed when using the raw materials. A relationship between hydrogen existing in an insulation film and, for example, negative bias temperature instability (NBTI), which indicates shifting of a threshold value when a P-channel MOSFET is turned on, has been pointed out. As described above, since hydrogen in a silicon nitride film may deteriorate reliability of the insulation film and adversely affect a device, it is thought that reduction of hydrogen in an insulation film by as much as possible is preferable.

Furthermore, in a thermal CVD method, since energy for dissociating a silicon containing gas, which is a raw material for film formation, is small, in the case where a tetrachlorosilane (SiCl₄) gas containing no hydrogen is selected as the silicon containing gas, it is necessary to perform film formation by using a NH₃, which is highly reactive, as a nitrogen containing gas, which is another raw material for film formation. Therefore, even in the thermal CVD method, it is unavoidable that a significant amount of hydrogen atoms are mixed into a formed silicon nitride film.

As a technique for forming an insulation film containing no hydrogen, patent reference 1 suggests a method of forming a silicon-based insulation film by depositing a silicon-based insulation film containing no hydrogen on a substrate using a hot-wall CVD method by introducing tetraisocyanatesilane, which is a silicon-based raw material containing no hydrogen, and an amine type 3 gas into a reaction container and reacting them to each other.

Furthermore, patent reference 2 also suggests a method of forming an oxynitride film substantially containing no hydrogen-related bond groups, such as H groups, —OH groups, or the like, or hydrogen-related bonds, such as Si—H bonds, Si—OH bonds, N—H bonds, or the like, by introducing a SiCl₄ gas, a N₂O gas, and a NO gas into a depressurized CVD device and performing depressurized CVD at a film formation temperature of 850° C. under a pressure of 2×10² Pa.

Furthermore, patent reference 3 suggests a method of manufacturing a semiconductor device including a process of forming a SiN film or a SiON film by using high density plasma CVD using an inorganic Si-based gas containing no H and N₂, NO, N₂O, or the like.

Furthermore, patent reference 4 suggests a method of forming a film composed of a nitrogen compound of silicon on an object to be processed by inducing a chemical reaction in plasma by using a growing gas including a compound of silicon halide and nitrogen or nitrogen.

Furthermore, patent reference 5 suggests a method of forming a silicon nitride film on a semiconductor substrate by introducing silicon difluoride gas and excited nitrogen gas.

Although the method disclosed in the patent reference 1 enables a process at a relatively low temperature around 200° C., the method is not a film formation technique using plasma. Furthermore, the method disclosed in the patent reference 2 is also not a film formation technique using plasma, and moreover, requires a relatively high film formation temperature of 850° C., and thus the method disclosed in the patent reference 2 may increase thermal budget and accordingly is not a satisfactory one.

Furthermore, a SiCl₄ gas used in the patent reference 1 and the patent reference 2 is excessively dissociated in plasma with a high electron temperature and forms an active species (etchant) having an etching effect, thus causing deterioration of film formation efficiency. In other words, a SiCl₄ gas is inappropriate as a raw material for film formation in plasma CVD.

Although the patent reference 3 states that a SiCl₄ gas may be used as “an inorganic Si-based gas containing no H,” a gas used for forming a SiN film in a corresponding embodiment is a SiF₄ gas. Similarly, a SiF₄ gas is used in formation of a SiN film in the patent reference 4. As stated above, the patent references 3 and 4 have statements related to film formation using plasma CVD by using a SiCl₄ gas as a raw material, but no actual verification has been made with respect thereto, and thus the statement is nothing more than an assumption. Furthermore, since the patent reference 3 provides no detailed disclosure regarding high density plasma, no resolution with respect to formation of etchants when the SiCl₄ gas is used is provided.

Although the patent reference 5 discloses formation of a silicon nitride film by generating a SiCl₂ gas and a NCl₂ gas by thermally dissociating SiCl₄ gas and NCl₃ gas and supplying the SiCl₂ gas and the NCl₂ gas to a surface of a silicon substrate (fifth embodiment), there is no detailed disclosure regarding usage of SiCl₄ as a raw material for film formation in plasma CVD.

Therefore, a technique for forming a fine quality silicon nitride film having high insulation properties by using plasma CVD method has not yet been established.

### PRIOR ART REFERENCE

### Patent Reference

(Patent Reference 1) Japanese Laid-Open Patent Publication No. hei 10-189582 (e.g., claim 1, or the like)
(Patent Reference 2) Japanese Laid-Open Patent Publication No. 2000-91337 (e.g., Paragraph 0033, or the like)
(Patent Reference 3) Japanese Laid-Open Patent Publication No. 2000-77406 (e.g., claim 1, claim 2, or the like)
(Patent Reference 4) Japanese Laid-Open Patent Publication No. sho 57-152132 (e.g. Claims, or the like)
(Patent Reference 5) Japanese Laid-Open Patent Publication No. 2000-114257 (e.g. Claim 1, Paragraph 0064, or the like)

### DISCLOSURE OF THE INVENTION

### Technical Problem

To solve the above and/or other problems, the present invention provides a high quality silicon nitride film containing substantially no hydrogen therein and having a high insulation property, and a process for production of the silicon nitride film by using a plasma CVD method.

### Technical Solution

According to an aspect of the present invention, there is provided a silicon nitride film produced by a plasma CVD device which generates plasma by introducing microwaves into a process chamber by using a planar antenna having a plurality of apertures, by performing plasma CVD by using process gases including a gas of a compound composed of silicon atoms and chlorine atoms and a nitrogen gas, wherein concentration of hydrogen atoms in the silicon nitride film is below or equal to 9.9×10²⁰ atoms/cm³ in the silicon nitride film as measured by using secondary ion mass spectrometry (SIMS).

No peak of N—H bonds may be detected from the silicon nitride film by using a Fourier transform infrared spectroscopy (FT-IR).

According to another aspect of the present invention, there is provided a process for production of a silicon nitride film on an object to be processed by using a plasma CVD method by using a plasma CVD device which generates plasma by introducing microwaves into a process chamber by using a planar antenna having a plurality of apertures, the process including forming a silicon nitride film with concentration of hydrogen atoms below or equal to 9.9×10²⁰ atoms/cm³ in the silicon nitride film as measured by using secondary ion mass spectrometry (SIMS) by setting a pressure inside the process chamber in the range from 0.1 Pa to 6.7 Pa and performing plasma CVD by using process gases including a gas of a compound composed of silicon atoms and chlorine atoms and a nitrogen gas.

The compound composed of silicon atoms and chlorine atoms may be tetrachlorosilane (SiCl₄).

A flow rate ratio of the SiCl₄ gas to the entire process gases may be in the range from 0.03% to 15%.

A flow rate ratio of the nitrogen gas to the entire process gases may be in the range from 5% to 99%.

According to another aspect of the present invention, there is provided a computer-readable storage medium having recorded thereon a control program to be operated on a computer, wherein the control program enables the computer to control a plasma CVD device that generates plasma by introducing microwaves into a process chamber by using a planar antenna having a plurality of apertures and performs film formation, to perform plasma CVD for forming a silicon nitride film with concentration of hydrogen atoms below or equal to 9.9×10²⁰ atoms/cm³ in the silicon nitride film as measured by using secondary ion mass spectrometry (SIMS) and by using process gases including a gas of compound composed of silicon atoms and chlorine atoms and a nitrogen gas and setting a pressure inside the process chamber in a range from 0.1 Pa to 6.7 Pa.

According to another aspect of the present invention, there is provided a plasma CVD device for production of a silicon nitride film on an object to be processed by using a plasma CVD method, the plasma CVD device including a process chamber which accommodates the object to be processed and has an opening on a top of the process chamber; a dielectric member which closes the opening of the process chamber; a planar antenna which is installed on the dielectric member and has a plurality of apertures for introducing microwaves into the process chamber and generating plasma; a gas introduction unit which is connected to a gas supply apparatus for supplying process gases into the process chamber; an exhauster which depressurizes and exhausts an inside of the process chamber; and a control unit that controls plasma CVD to be performed to set a pressure inside the process chamber to be in a range from 0.1 Pa to 6.7 Pa and to produce the silicon nitride film having concentration of hydrogen atoms below or equal to 9.9×10²⁰ atoms/cm³ in the silicon nitride film as measured by using secondary ion mass spectrometry (SIMS), by using the process gases including a gas of a compound composed of silicon atoms and chlorine atoms and nitrogen gas from the gas introduction unit connected to the gas supply apparatus.

### Advantageous Effects

A silicon nitride film according to the present invention contains concentration of hydrogen atoms below or equal to 9.9×10²⁰ atoms/cm³ in the silicon nitride film as measured by using secondary ion mass spectrometry (SIMS) and contains substantially no hydrogen therein. Therefore, the silicon nitride film causes no adverse effects on a device due to hydrogen and has excellent insulating properties, and thus the silicon nitride film can provide high reliability to a device. Accordingly, the silicon nitride film according to the present invention has a high utility value for a purpose, for example, for a gate insulation film, a liner around the gate insulation film, an interlayer insulation film, a passivation film, an etching stopper film, etc.

Also, in a process for production of a silicon nitride film according to the present invention, a high quality silicon nitride film with high insulating properties, concentration of hydrogen atoms below or equal to 9.9×10²⁰ atoms/cm³ in the silicon nitride film as measured by using secondary ion mass spectrometry (SIMS), and substantially no hydrogen therein may be formed by a plasma CVD method by using a SiCl₄ gas and a nitrogen gas as raw materials for film formation,

### BRIEF DESCRIPTION OF THE DRAWINGS

FIG. 1 is a schematic cross-sectional view showing an example of a plasma CVD device suitable for forming a silicon nitride film;

FIG. 2 is a diagram of a structure of a planar antenna;

FIG. 3 is a diagram for explaining a structure of a control unit;

FIGS. 4A and 4B are diagrams showing an example of processes of a method for forming a silicon nitride film of the present invention;

FIGS. 5A through 5C are graphs showing dependence of refractive index of a silicon nitride film of the present invention with respect to a process pressure during film formation, a microwave output, and a flow rate of a N₂ gas, respectively;

FIGS. 6A through 6C are graphs showing results of SIMS measurement;

FIGS. 7A and 7B are graphs showing results of FT-IR measurement; and

FIG. 8 is a graph showing a result of a wet etching test.

### BEST MODE FOR CARRYING OUT THE INVENTION

### First Embodiment

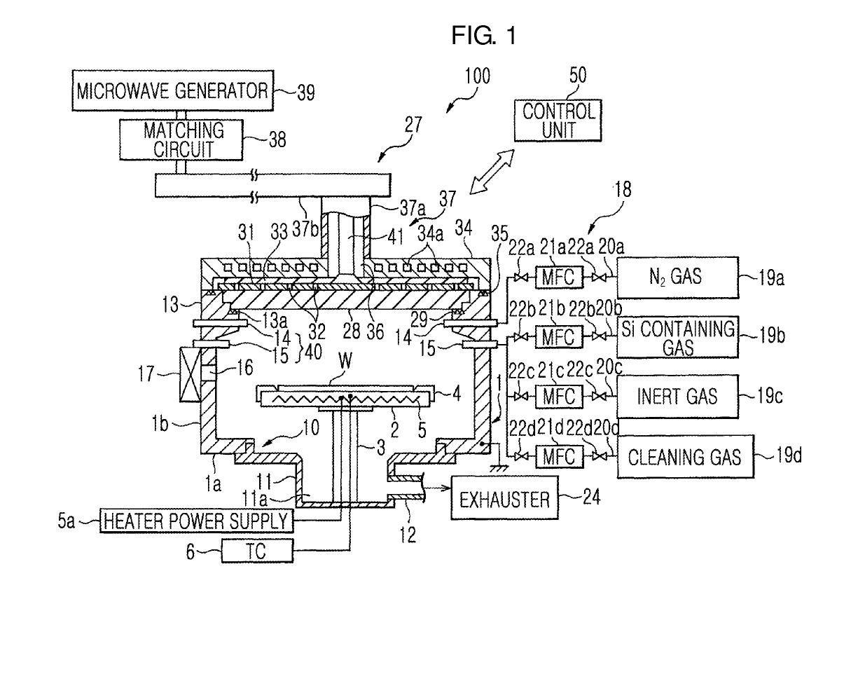

Hereinafter, the present invention will be described in detail by explaining exemplary embodiments of the invention with reference to the attached drawings. FIG. 1 is a schematic cross-sectional view showing a schematic structure of a plasma CVD device 100 used in a process for production of a silicon nitride film according to the present invention.

The plasma CVD device 100 is configured as a RLSA (Radial Line Slot Antenna) microwave plasma process apparatus that can generate microwave excitation plasma having a high density and a low electron temperature, by generating plasma by introducing microwaves into a process chamber by using a planar antenna including a plurality of apertures each having a slot shape, specifically a RLSA. The plasma CVD device 100 is able to perform a process using plasma having a low electron temperature from 0.7 eV to 2 eV, and a plasma density from 1×10¹⁰/cm³ to 5×10¹²/cm³. Accordingly, the plasma CVD device 100 may be very suitably used to form a silicon nitride film by using plasma CVD while manufacturing various semiconductor devices.

Important elements of the plasma CVD device 100 include an airtight process chamber 1, gas introduction units 14 and 15 connected via a gas introduction pipe to a gas supply apparatus 18 for supplying a gas into the process chamber 1, an exhauster 24 constituting an exhaust apparatus for depressurizing and exhausting an inside of the process chamber 1, a microwave introduction apparatus 27 disposed above the process chamber 1 and for introducing microwaves into the process chamber 1, and a control unit 50 for controlling each element of the plasma CVD device 100. Also, in the embodiment of FIG. 1, the gas supply apparatus 18 is integrally installed to the plasma CVD device 100, but may not be integrally installed. The gas supply apparatus 18 may be installed outside the plasma CVD device 100.

The process chamber 1 is a grounded container having an approximately cylindrical shape. Alternatively, the process chamber 1 may be a container having a prismatic shape. The process chamber 1 has a bottom wall 1a and a side wall 1b that are formed of a material such as aluminum or the like.

A holding stage 2 for horizontally supporting a silicon wafer (hereinafter, simply referred to as a “wafer”) W constituting an object to be processed is installed inside the process chamber 1. The holding stage 2 is formed of a material having a high thermal conductivity, for example, a ceramic, such as AlN or the like. The holding stage 2 is supported by a supporting member 3 having a cylindrical shape extending upward from a bottom center of an exhaust chamber 11. The supporting member 3 may be formed of a ceramic, such as AlN or the like.

A cover ring 4 for covering an outer edge portion of the holding stage 2 and guiding the wafer W is installed on the holding stage 2. The cover ring 4 is a ring-shaped member formed of a material such as quartz, AlN, Al₂O₃, SiN, or the like.

A resistance heating type heater 5 is embedded in the holding stage 2, to serve as a temperature adjusting apparatus. The heater 5 heats the holding stage 2 by receiving power from a heater power supply 5a, and the wafer W constituting a substrate to be processed is uniformly heated by heat from the holding stage 2.

A thermocouple (TC) 6 is disposed at the holding stage 2. A temperature is measured by using the thermocouple 6, and thus a heating temperature of the wafer W is controllable, for example, in the range from room temperature to 900° C.

Also, the holding stage 2 includes wafer support pins (not shown) for supporting and elevating the wafer W. Each wafer support pin is installed to be able to protrude and retract with respect to a surface of the holding stage 2.

A circular opening 10 is formed around a center of the bottom wall 1a of the process chamber 1. The exhaust chamber 11, which protrudes downward from the bottom wall 1a and communicates with the opening 10, is continuously installed on the bottom wall 1a. The exhaust chamber 11 is connected to an exhaust pipe 12, and is connected to the exhauster 24 through the exhaust pipe 12.

A ring-shaped plate 13 functioning as a lid for opening and closing the process chamber 1 is disposed on an upper end of the side wall 1b forming the process chamber 1. The plate 13 has an opening therein, and an inner circumference of the plate 13 protrudes inward (toward a space inside the process chamber) to form a ring-shaped supporter 13a.

A gas introduction unit 40 is disposed at the plate 13, and the gas introduction unit 14 having a ring shape and a first gas introduction hole is installed to the gas introduction unit 40. Also, the gas introduction unit 15 having a ring shape and a second gas introduction hole is installed on the side wall 1b of the process chamber 1. In other words, the gas introduction units 14 and 15 are installed in two stages consisting of a top stage and a bottom stage. Each of the gas introduction units 14 and 15 is connected to the gas supply apparatus 18 for supplying process gases. Alternatively, the gas introduction units 14 and 15 may each have a nozzle shape or a shower head shape. Alternatively, the gas introduction units 14 and 15 may be installed as a single shower head.

A transfer hole 16 for transferring the wafer W between the plasma CVD device 100 and a transfer chamber (not shown) adjacent to the plasma CVD device 100, and a gate valve 17 for opening and closing the transfer hole 16 are installed on the side wall 1b of the process chamber 1.

The gas supply apparatus 18 includes, for example, a nitrogen gas supply source 19a, a silicon (Si) containing gas supply source 19b, an inert gas supply source 19c, and a cleaning gas supply source 19d. The nitrogen gas supply source 19a is connected to the gas introduction unit 14 as the top stage of the two stages. Also, the Si-containing gas supply source 19b, the inert gas supply source 19c, and the cleaning gas supply source 19d are connected to the gas introduction unit 15 as the bottom stage of the two stages. The cleaning gas supply source 19d is used to clean unnecessary films deposited inside the process chamber 1. Also, the gas supply apparatus 18 includes, for example, a purge gas supply source or the like used to replace an atmosphere inside the process chamber 1, as another gas supply source (not shown).

In the present invention, a gas of a compound composed of silicon atoms and chlorine atoms, for example, a gas of a compound indicated in the form of SiₙCl₂ₙ₊₂, such as tetrachlorosilane (SiCl₄), hexachlorosilane (Si₂Cl₆), or the like, is used as the silicon (Si) containing gas. Since SiCl₄ and N₂ do not contain hydrogen in raw material gas molecules, SiCl₄ and N₂ may be preferably used in the present invention. Also, for example, a rare gas may be used as the inert gas. The rare gas helps generation of stable plasma, as a plasma excitation gas, and for example, an Ar gas, a Kr gas, a Xe gas, a He gas, or the like may be used as the rare gas.

The N₂ gas reaches the gas introduction unit 14 from the nitrogen gas supply source 19a of the gas supply apparatus 18 through a gas line 20a, and is introduced into the process chamber 1 from a gas introduction hole (not shown) of the gas introduction unit 14. Meanwhile, the Si-containing gas, the inert gas, and the cleaning gas reach the gas introduction unit 15 respectively from the Si-containing gas supply source 19b, the inert gas supply source 19c, and the cleaning gas supply source 19d respectively through the gas lines 20b, 20c, and 20d, and are introduced into the process chamber 1 from a gas introduction hole (not shown) of the gas introduction unit 15. Mass flow controllers 21a through 21d and opening and closing valves 22a through 22d respectively in front and behind the mass flow controllers 21a through 21d are respectively installed in the gas lines 20a through 20d respectively connected to the gas supply sources. Switch of supplied gases, a flow rate, and the like are controllable by such a structure of the gas supply apparatus 18. Here, the rare gas for plasma excitation, such as Ar gas or the like, is a predetermined gas, and does not have to be supplied at the same time as with process gases, but may be added in order to stabilize plasma. Particularly, the Ar gas may be used as a carrier gas for stably supplying the SiCl₄ gas into the process chamber.

The exhauster 24 constituting an exhaust apparatus includes a high speed vacuum pump, such as a turbomolecular pump or the like. As described above, the exhauster 24 is connected to the exhaust chamber 11 of the process chamber 1 through the exhaust pipe 12. By operating the exhauster 24, a gas inside the process chamber 1 uniformly flows inside a space 11a of the exhaust chamber 11, and is then exhausted from the space 11a to an exterior through the exhaust pipe 12. Accordingly, it is possible to depressurize the inside of the process chamber 1, for example, up to 0.133 Pa, at a high speed.

A structure of the microwave introduction apparatus 27 will now be described. Important elements of the microwave introduction apparatus 27 include a penetration plate 28, a planar antenna 31, a wavelength-shortening material 33, a cover 34, a waveguide 37, and a microwave generator 39.

The penetration plate 28 through which microwaves penetrate is arranged on the supporter 13a protruding in a long manner toward an inner circumference of the plate 13. The penetration plate 28 is formed of a dielectric material, for example, a ceramic such as quartz, Al₂O₃, AlN, or the like. A space between the penetration plate 28 and the supporter 13a is sealed air tight by disposing a seal member 29. Accordingly, the process chamber 1 is held air tight.

The planar antenna 31 is installed above the penetration plate 28 to face the holding stage 2. The planar antenna 31 has a disk shape. However, a shape of the planar antenna 31 is not limited to the disk shape, and, for example, the planar antenna 31 may have a rectangular plate shape. The planar antenna 31 is engaged with a top end of the plate 13.

The planar antenna 31 is formed of, for example, a plate such as a copper plate, a nickel plate, a SUS plate, or an aluminum plate, which has a surface coated with gold or silver. The planar antenna 31 includes a plurality of microwave radiation holes 32 each having a slot shape and for radiating microwaves. The microwave radiation holes 32 penetrate and are arranged through the planar antenna 31 in a predetermined pattern.

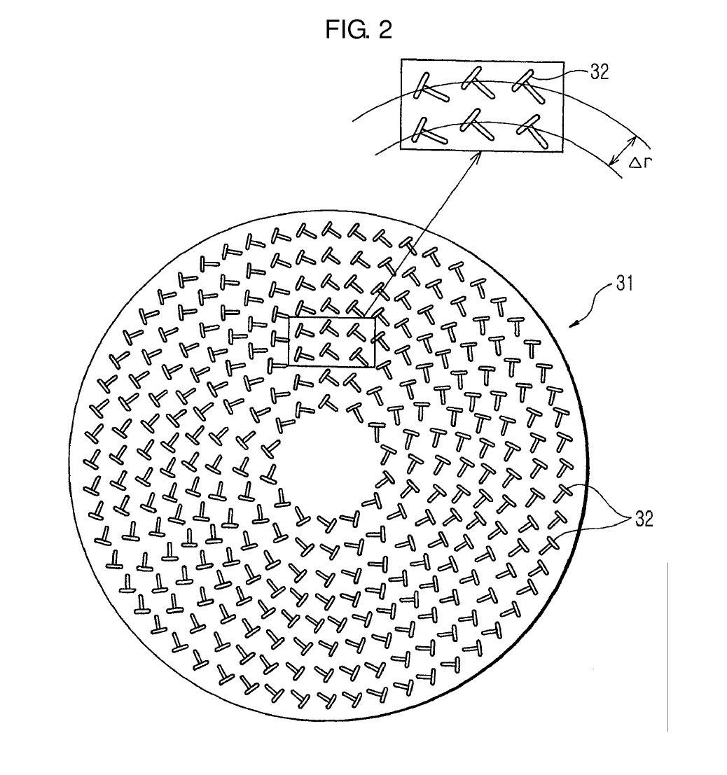

Each microwave radiation hole 32 has, for example, a thin and long rectangular shape (slot shape) as shown in FIG. 2, and two adjacent microwave radiation holes form a pair. The adjacent microwave radiation holes 32 are typically arranged in a “L” or “V” shape. Also, the microwave radiation holes 32 disposed after combining in such a predetermined shape are also arranged overall in a concentric shape.

Lengths or arranged intervals of the microwave radiation holes 32 are determined according to a wavelength (λg) of microwaves. For example, an interval of the microwave radiation holes 32 is arranged to be from

$$\frac{λ g}{4}$$

to λg. In FIG. 2, an interval between the adjacent microwave radiation holes 32 arranged in a concentric shape is Δr. Alternatively, a shape of microwave radiation hole 32 may vary and be, for example, a circular shape, an arc shape, or the like. Also, an arrangement of the microwave radiation holes 32 is not specifically limited, and may be, for example, a spiral shape, a radial shape or the like, aside from the concentric shape.

The wavelength-shortening material 33, having a dielectric constant higher than vacuum, is installed on a top surface of the planar antenna 31. The wavelength-shortening material 33 shortens a wavelength of microwaves in order to adjust plasma, since the wavelength of the microwaves lengthens in a vacuum.

Also, the planar antenna 31 and the penetration plate 28, and the wavelength-shortening material 33 and the planar antenna 31 may contact or be separated from each other, but preferably contact each other.

The cover 34 may be formed on an upper portion of the process chamber 1 so as to cover the planar antenna 31 and the wavelength-shortening material 33. The cover 34 may be formed of, for example, a metal material such as aluminum, stainless steel, or the like. A top of the plate 13 and the cover 34 are sealed by a seal member 35. A cooling water path 34a may be formed inside the cover 34. Cooling water flows through the cooling water path 34a, thereby cooling the cover 34, the wavelength-shortening material 33, the planar antenna 31, and the penetration plate 28. Also, the cover 34 is grounded.

An opening 36 is formed on a center of a top wall (ceiling portion) of the cover 34, and the waveguide 37 is connected to the opening 36. Another end of the waveguide 37 is connected to the microwave generator 39 for generating microwaves, through a matching circuit 38.

The waveguide 37 includes a coaxial waveguide 37a having a circular cross-section and extending upward from the opening 36 of the cover 34, and a rectangular waveguide 37b connected to an upper end of the coaxial waveguide 37a and extending in a horizontal direction.

An inner conductor 41 extends in a center of the coaxial waveguide 37a. A bottom portion of the inner conductor 41 is connected and fixed to a center of the planar antenna 31. According to such a structure, microwaves are efficiently uniformly propagated in a radial shape to the planar antenna 31 through the inner conductor 41 of the coaxial waveguide 37a.

By using the microwave introduction apparatus 27 having the above structure, microwaves generated in the microwave generator 39 are propagated to the planar antenna 31 through the waveguide 37, and then are introduced into the process chamber 1 through the penetration plate 28. Also, a frequency of the microwaves may be, for example, 2.45 GHz, and may be 8.35 GHz, 1.98 GHz, or the like, aside from 2.45 GHz.

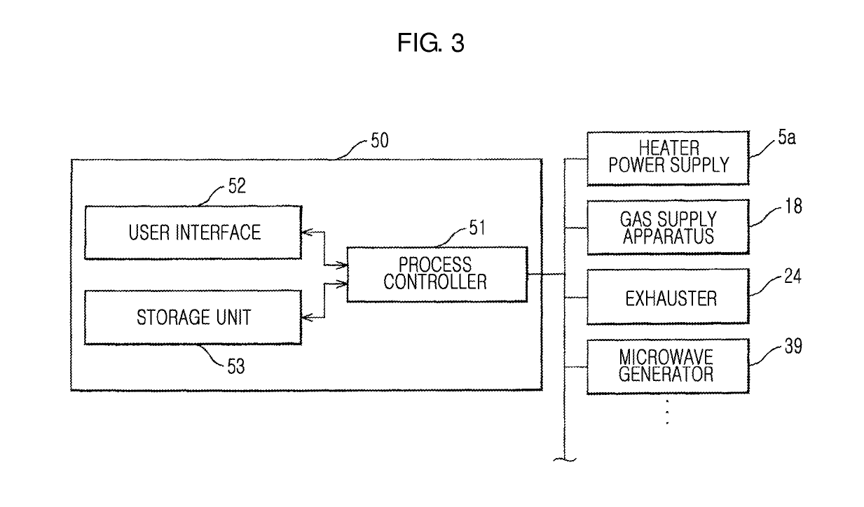

Each element of the plasma CVD device 100 is connected to and controlled by the control unit 50. The control unit 50 includes a computer, and, for example, includes a process controller 51 having a CPU, and a user interface 52 and a storage unit 53 connected to the process controller 51, as shown in FIG. 3. The process controller 51 is a control unit that generally controls elements of the plasma CVD device 100 that are related to, for example, process conditions, such as a temperature, a pressure, a gas flow rate, a microwave output, etc. (for example, the heater power supply 5a, the gas supply apparatus 18, the exhauster 24, the microwave generator 39, etc.).

The user interface 52 includes a keyboard for an operation manager to perform input manipulation or the like of a command to manage the plasma CVD device 100, a display for visually displaying an operation situation of the plasma CVD device 100, and the like. Also, the storage unit 53 stores a control program (software) for executing various processes in the plasma CVD device 100 under a control of the process controller 51, or a recipe on which process condition data, etc. is recorded.

Also, if required, a predetermined recipe is called from the storage unit 53 via instructions from the user interface 52 or the like and executed in the process controller 51, thereby performing a desired process in the process chamber 1 of the plasma CVD device 100 under a control of the process controller 51. The control program and the recipe recording process condition data or the like may be stored in a computer readable storage medium, such as a CD-ROM, a hard disk, a flexible disk, a flash memory, a DVD, a Blu-ray disk, or the like, and accessed therefrom. Alternatively, the control program, the recipe, such as the process condition data, or the like may be frequently received from another device, for example, through an exclusive line, and accessed online.

Next, a deposition process of a silicon nitride film by using a plasma CVD method using the RLSA type plasma CVD device 100 will be described. First, the gate valve 17 is opened and the wafer W is transferred to the process chamber 1 through the transfer hole 16 and placed and heated on the holding stage 2. Then, while depressurizing and exhausting the inside of the process chamber 1, the SiCl₄ gas, the nitrogen gas, and, if required, Ar gas are introduced into the process chamber 1 respectively from the nitrogen gas supply source 19a, the Si-containing gas supply source 19b, and the inert gas supply source 19c of the gas supply apparatus 18 respectively through the gas introduction units 14 and 15, at predetermined flow rates. Also, the inside of the process chamber 1 is set to a predetermined pressure. Conditions at this time will be described later.

Then, microwaves of a predetermined frequency, for example, 2.45 GHz, generated in the microwave generator 39 are led to the waveguide 37 through the matching circuit 38. The microwaves led to the waveguide 37 sequentially pass through the rectangular waveguide 37b and the coaxial waveguide 37a, and are supplied to the planar antenna 31 through the inner conductor 41. The microwaves are propagated in a radial shape from the coaxial waveguide 37a toward the planar antenna 31. Also, the microwaves are radiated to a space above the wafer W in the process chamber 1 from the microwave radiation holes 32 each having a slot shape of the planar antenna 31 through the penetration plate 28.

An electric field is formed inside the process chamber 1 by the microwaves radiated to the process chamber 1 from the planar antenna 31 through the penetration plate 28, and thus the nitrogen gas and the SiCl₄ gas are each plasmatized. Ar gas may be added, if required. In this case, a flow rate of the Ar gas may be smaller than a total flow rate of N₂ and SiCl₄ gases in consideration of damages to a film or acceleration of dissociation of SiCl₄. Then, a raw gas is efficiently dissociated in the plasma, and a thin film of silicon nitride (SiN; here, a composition ratio of Si and N is not definitely determined stoichiometrically, but has different values according to film formation conditions. The same is applied hereinafter) is deposited by a reaction of active species of SiCl₃, N, etc. (ions, radicals, etc.) After forming the silicon nitride film on a substrate, a ClF₃ gas is supplied as a cleaning gas into the chamber and the chamber is cleaned by being heated from 100° C. to 500° C., preferably from 200° C. to 300° C., to remove silicon nitride films deposited in the chamber. Alternatively, when NF₃ gas is used as a cleaning gas, plasma is generated at a temperature from room temperature to 300° C. and the silicon nitride films deposited in the chamber are removed.

The above conditions are stored as a recipe in the storage unit 53 of the control unit 50. Also, the process controller 51 reads the recipe, and transmits a control signal to each element of the plasma CVD device 100, for example, the heater power supply 5a, the gas supply apparatus 18, the exhauster 24, the microwave generator 39, etc., thereby realizing a plasma CVD process performed under a desired condition.

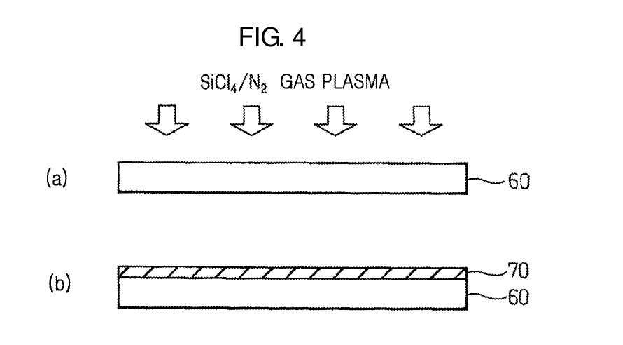

FIGS. 4A and 4B are process diagrams showing processes of forming a silicon nitride film performed by the plasma CVD device 100. As shown in FIG. 4A, a plasma CVD process is performed on a predetermined base layer (for example, a Si substrate) 60 by using the plasma CVD device 100. The plasma CVD process is performed under following conditions by using film formation gas including the SiCl₄ gas, and the nitrogen gas.

A process pressure may be set in the range from 0.1 Pa to 6.7 Pa, and preferably in the range from 0.1 Pa to 4 Pa. The lower the process pressure the better, and the lowest limit 0.1 Pa of the range is set based on a restriction of a device (limitation of a high vacuum level). When the process pressure exceeds 6.7 Pa, a SiCl₄ gas does not dissociate, and thus a film may not be sufficiently formed.

Also, a ratio of a flow rate of the SiCl₄ gas to a flow rate of all process gases (a percentage of

$$\frac{flow rate of {SiCl}_{4} gas}{flow rate of all process gases}$$

) may be from 0.03% to 15%, and preferably from 0.03% to 1%. Also, the flow rate of the SiCl₄ gas may be set to be from 0.5 mL/min (sccm) to 10 mL/min (sccm), and preferably from 0.5 mL/min (sccm) to 2 mL/min (sccm).

Also, a ratio of a flow rate of the nitrogen gas to the flow rate of the all process gases (for example, a percentage of

$$\frac{flow rate of {N}_{2} gas}{flow rate of all process gases}$$

) may be from 5% to 99%, and preferably from 40% to 99%. Also, the flow rate of the nitrogen gas may be set to be from 50 mL/min (sccm) to 1000 mL/min (sccm), preferably from 300 mL/min (sccm) to 1000 mL/min (sccm), and more preferably from 300 mL/min (sccm) to 600 mL/min (sccm).

Also, a ratio of gas flow rates of

$$\frac{{SiCl}_{4}}{{N}_{2}}$$

may be below or equal to 0.005.

Also, a ratio of a flow rate of the Ar gas to the flow rate of the all process gases (for example, a percentage of

$$\frac{flow rate of Ar gas}{flow rate of all process gases}$$

) may be from 0 to 90%, and preferably from 0 to 60%. More preferably, a flow rate of the Ar gas may be smaller than a sum of flow rates of the N₂ gas and the SiCl₄ gas. Also, the flow rate of the inert gas may be set to be from 0 mL/min (sccm) to 1000 mL/min (sccm), and preferably from 0 mL/min (sccm) to 200 mL/min (sccm).

Also, a temperature of the plasma CVD process may be set to be such that a temperature of the holding stage 2 is from 300° C. to 600° C., and preferably from 400° C. to 550° C.

Also, a microwave output in the plasma CVD device 100 may be in the range from 0.25 W/cm² to 2.56 W/cm² as power density per area of the penetration plate 28, and preferably from 0.767 W/cm² to 2.56 W/cm². The microwave output may be selected to be a power density within the range, for example, from 500 W to 5000 W, according to a purpose, and preferably from 1500 W to 5000 W.

SiCl₄/N₂ gas plasma is formed via plasma CVD, and as shown in FIG. 4B, a silicon nitride film (SiN film) 70 may be deposited. The plasma CVD device 100 is advantageous since the silicon nitride film having a film thickness in the range, for example, from 2 nm to 300 nm, preferably from 2 nm to 50 nm, is formed by using the plasma CVD device 100.

The silicon nitride film 70 obtained as described above is dense, has excellent insulating properties, and contains no hydrogen atoms H originated from a raw material for film formation. In other words, the silicon nitride film 70 is an insulation film containing no hydrogen atoms originated from a raw material. Therefore, adverse effects on a device due to hydrogen (e.g., NBTI) may be prevented, and thus reliability of the device may be improved. Accordingly, the silicon nitride film 70 formed by using the method of the present invention may preferably be used for a purpose, for example, for a gate insulation film, a liner around a gate insulation film, an interlayer insulation film, a passivation film, an etching stopper film, etc.

### (Mechanism)

In the process for production of a silicon nitride film according to the present invention, a silicon nitride film containing substantially no hydrogen atoms H originated from a raw material for film formation may be formed by using process gases including SiCl₄ and nitrogen gas as the raw material for film formation. It is thought that the SiCl₄ gas used in the present invention is dissociated in plasma according to following steps from i) to iv).

SiCl₄→SiCl₃+Cl i

SiCl₃→SiCl₂+Cl+Cl ii

SiCl₂→SiCl+Cl+Cl+Cl iii

SiCl→Si+Cl+Cl+Cl+Cl iv

### (Here, Cl Denotes Ions)

In plasma having a high electron temperature, such as plasma used in a conventional plasma CVD method, the dissociation reaction shown in the i) to iv) may easily occur due to high energy of the plasma, and thus SiCl₄ molecules are easily separated and apt to become a high dissociated state. Thus, etching dominated as a large amount of etchant, such as Cl ions or the like constituting active species having an etching effect, was generated from the SiCl₄ molecules, and thus a silicon nitride film could not be deposited. Accordingly, until now, the SiCl₄ gas was not used as a film formation raw material of plasma CVD executed on an industrial scale.

The plasma CVD device 100 used in the method of the present invention was able to form plasma having a low electron temperature via a configuration of generating plasma by introducing microwaves into the process chamber 1 by using the planar antenna 31 having a plurality of slots (the microwave radiation holes 32). Thus, energy of plasma is low even if the SiCl₄ gas is used as a film formation raw material by controlling a process pressure and a flow rate of the process gases to be within the above ranges by using the plasma CVD device 100. Accordingly, dissociation is largely performed on SiCl₃ and SiCl₂, thereby maintaining a low dissociation state, and thus film formation dominates. In other words, dissociation of SiCl₄ molecules is suppressed in the steps of i) or ii) by plasma having a low electron temperature and low energy, thereby suppressing formation of the etchant (Cl ions or the like) that adversely affects film formation, and thus the film formation dominates.

Since the plasma of the method of the present invention has a low electron temperature and a high concentration of electron density, dissociation of the SiCl₄ gas is easy, and thus a lot of SiCl₃ ions are generated, and even a nitrogen gas (N₂) having high bonding energy is dissociated in high concentration plasma to become N ions. Also, it is thought that SiN is generated as SiCl₃ ions and N ions react with each other. Accordingly, by using the nitrogen gas (N₂), it is possible to form a silicon nitride film. Accordingly, it is possible to form a high quality silicon nitride film having small film damage by ions and a very low hydrogen amount, by using plasma CVD in which the SiCl₄ gas is used as a raw material.

Also, since the a raw material gas for film formation is not rapidly dissociated by plasma and is dissociated mildly by using mild plasma having a low electron temperature in the plasma CVD device 100, a deposition speed (film formation rate) of a silicon nitride film is easily controlled. Accordingly, film formation may be performed while controlling a film thickness, for example, from a thin film thickness of about 2 nm to a relatively thick film thickness of about 300 nm.

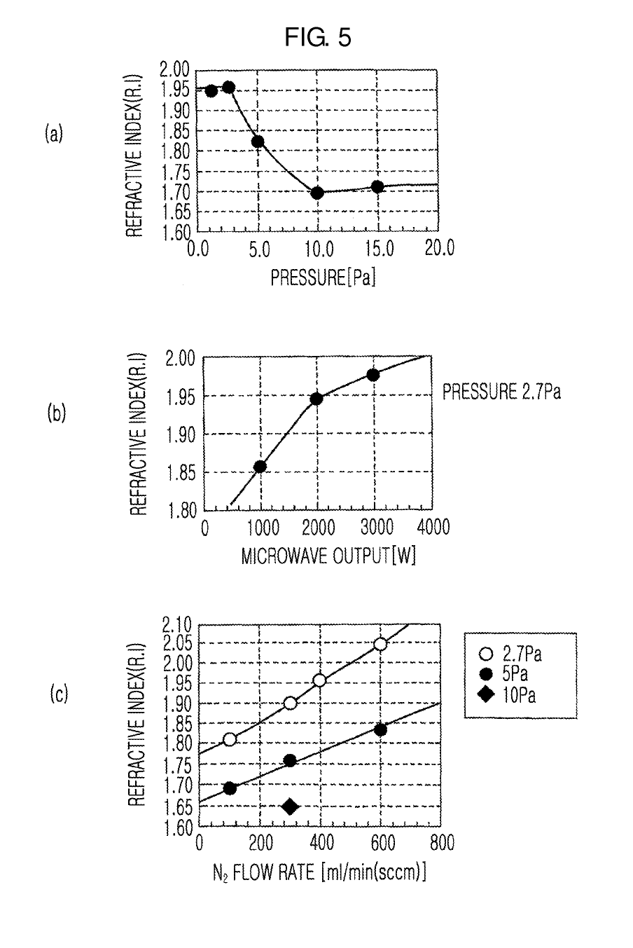

FIGS. 5A through 5C show relationships between refractive index of a silicon nitride film and a process pressure, between the refractive index of the silicon nitride film and a microwave output, and between the refractive index of the silicon nitride film and a flow rate of a nitrogen gas (N₂), respectively. Here, film formation conditions of FIGS. 5A through 5C are basically as follows:

(Plasma CVD Conditions)

process temperature (holding stage): 500° C.

microwave power: 3 kW (power density 1.53 W/cm²)

process pressure: 2.7 Pa

SiCl₄ flow rate: 1 mL/min (sccm)

N₂ gas flow rate: 400 mL/min (sccm)

FIG. 5A shows a relationship between the refractive index of the silicon nitride film and the process pressure during formation of the silicon nitride film. It is determined from FIG. 5A that the refractive index tends to increase as the process pressure decreases. Therefore, a refractive index is about 1.82 under a process pressure of 5 Pa and a refractive index is greater than 1.85 under a process pressure of 4 Pa, and thus the refractive indexes are preferable. Also, a refractive index is 1.70, which is low, under a process pressure of 10 Pa, and thus the refractive index is not preferable.

FIG. 5B shows a relationship between the refractive index of the silicon nitride film and the microwave output during formation of the silicon nitride film. It is determined from FIG. 5B that the refractive index tends to increase as the microwave output increases, and thus, when the microwave output is equal to or above 1000 W, the refractive index is equal to or above 1.85, and thus the refractive index is preferable.

FIG. 5C shows a relationship between the refractive index of the silicon nitride film and the flow rate of nitrogen gas (N₂) during formation of the silicon nitride film. It is determined from FIG. 5C that the refractive index tends to increase as the process pressure decreases and a flow rate of the nitrogen gas (N₂) increases. Therefore, under a process pressure of 5 Pa, a flow rate of the nitrogen gas (N₂) is 600 mL/min (sccm), and the refractive index is about 1.85, and thus the refractive index is preferable. Also, under a process pressure of 2.7 Pa, a flow rate of the nitrogen gas (N₂) is 300 mL/min (sccm), and the refractive index is 1.90, which is high, and thus the refractive index is more preferable. However, under a process pressure of 10 Pa, a flow rate of the nitrogen gas (N₂) is 300 mL/min (sccm), and refractive index is 1.65, which is low, and thus the refractive index is not preferable.

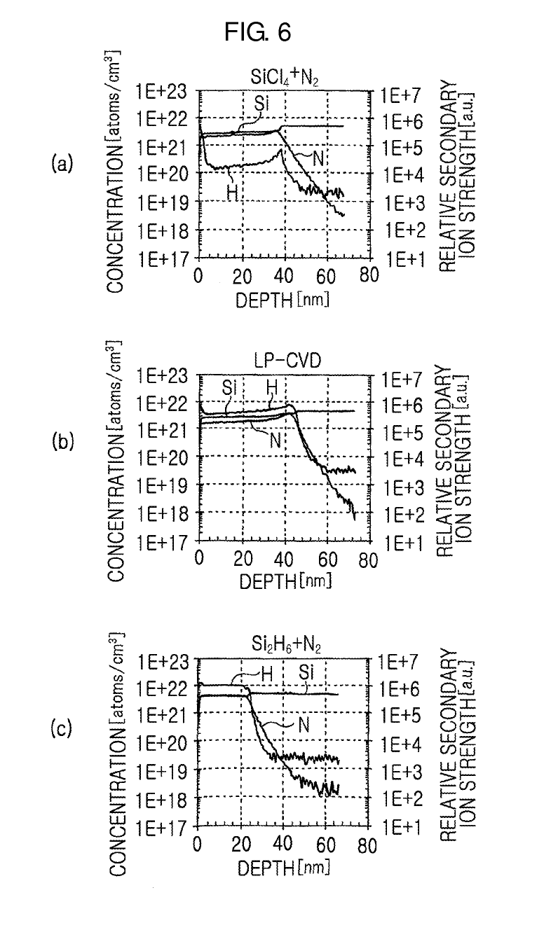

Next, descriptions of experiment data from which effects of the present invention were determined will be given. Here, in the plasma CVD device 100, a silicon nitride film having a thickness of 50 nm was formed on a silicon substrate by using a SiCl₄ gas and a N₂ gas as raw material gases for film formation under following conditions. A concentration of each of hydrogen, nitrogen, and silicon atoms was measured by using secondary ion mass spectrometry (RBS-SIMS), with respect to the silicon nitride film. Results thereof are shown in FIG. 6.

Also, for comparison, the same measurements are made with respect to a silicon nitride film formed by plasma CVD under the same conditions as those in the present invention except for using disilane (Si₂H₆) instead of SiCl₄ as raw material for film formation and a silicon nitride film formed by LPCVD (Low Pressure CVD) according to following conditions, were also measured.

(Plasma CVD Conditions)

process temperature (holding stage): 400° C.

microwave power: 3 kW (power density 1.53 W/cm², per penetration plate area)

process pressure: 2.7 Pa

SiCl₄ flow rate (or Si₂H₆ flow rate): 1 mL/min (sccm)

N₂ gas flow rate: 450 mL/min (sccm)

Ar gas flow rate: 40 mL/min (sccm)

(LPCVD Conditions)

process temperature: 780° C.

process pressure: 133 Pa

SiH₂Cl₂ gas+NH₃ gas: 100+1000 mL/min (sccm)

SIMS measurements were performed under following conditions.

Used apparatus: ATOMIKA 4500 type (manufactured by ATOMIKA) secondary ion mass spectrometry apparatus

first ion condition: Cs⁺, 1 keV, and about 20 nA

radiated region: about 350×490 μm

analyzed region: about 65×92 μm

secondary ion polarity: negative

electrification compensation: present

Also, a hydrogen atom amount in the SIMS result is obtained by converting secondary ionic strength of H to an atom concentration by using a relative sensitivity factor (RSF) calculated by using a H concentration (6.6×10²¹ atoms/cm³) of an amount of a standard sample fixed by RBS/HR-ERDA (High Resolution Elastic Recoil Detection Analysis) (RBS-SIMS Measuring Method).

FIG. 6A shows a result of the measurement with respect to a silicon nitride film formed by using SiCl₄+N₂ (the method of the present invention), FIG. 6B shows a result of the measurement with respect to a silicon nitride film formed by using LPCVD, and FIG. 6C shows a result of the measurement with respect to a silicon nitride film formed by using of Si₂H₆+N₂ as raw material. It is determined from FIG. 6, that a concentration of hydrogen atoms included in the SiN film formed by the method of the present invention was 2×10²⁰ atoms/cm³ in the SiN film, which is a detection limit level of a SIMS-RBS measuring device. Meanwhile, concentrations of hydrogen atoms included in the SiN film formed by using LPCVD and the SiN film formed by using Si₂H₆+N₂ were equal to or above 2×10²¹ atoms/cm³ and 1×10²² atoms/cm³, respectively. Based on the above results, it was determined that the SiN film obtained by the method of the present invention contained substantially no hydrogen, unlike a SiN film obtained by using a conventional method. In other words, according to the method of the present invention, a SiN film having concentration of hydrogen atoms below or equal to 9.9×10²⁰ atoms/cm³ in the SiN film may be formed.

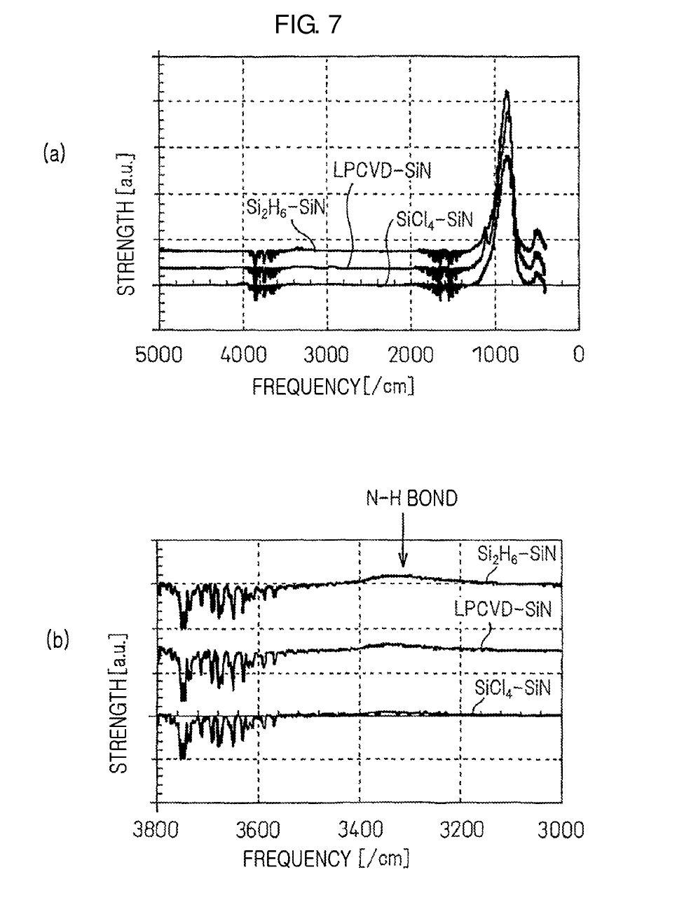

Furthermore, measurements using a Fourier transform infrared spectroscopy (FT-IR) were performed with respect to the silicon nitride film formed by using SiCl₄+N₂ (the method of the present invention), the silicon nitride film formed by using LPCVD, and the silicon nitride film formed by using of Si₂H₆+N₂ as raw material. Results of the measurements are shown in FIGS. 7A and 7B. Also, FIG. 7B is a magnified view of major portions of FIG. 7A. Although peaks unique to N—H bonds were detected around a frequency of 3300 [/cm] in the cases of the silicon nitride film formed by using LPCVD and the silicon nitride film formed by using of Si₂H₆+N₂ as raw material, the peak was not detected in the silicon nitride film of the present invention using SiCl₄+N₂ as raw material. According to such results, it was determined that N—H bonds in the silicon nitride film using SiCl₄+N₂ as raw material is equal to or below the lowest limit of detection.

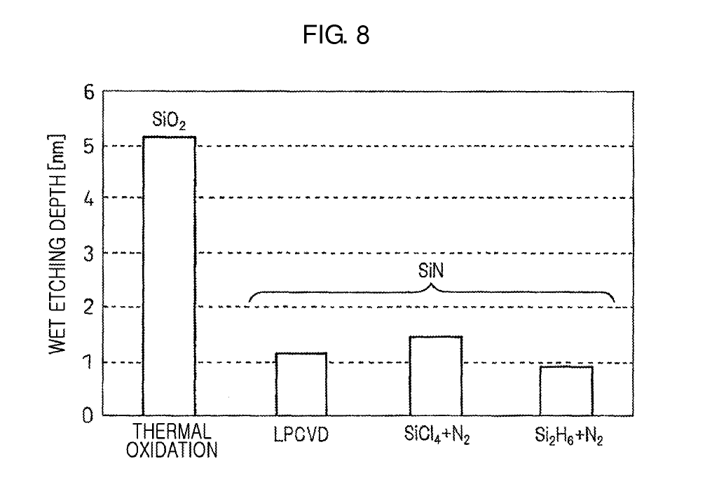

Next, each SiN film formed under the above conditions was processed with dilute hydrofluoric acid (HF) of 0.5 wt % concentration for 60 seconds to measure an etching depth, thereby evaluating etching tolerance. Results thereof are shown in FIG. 8. Also, for comparison, FIG. 8 also shows a result of the same evaluation with respect to a silicon oxide film formed at 950° C. by thermal oxidation (WVG: method of generating and supplying vapor by combusting O₂ and H₂ by using a vapor generator).

An etching rate of a SiN film obtained by using SiCl₄+N₂ as film formation raw material according to the method of the present invention was 0.025 nm/s. Meanwhile, an etching rate of a SiO₂ film obtained by using Si₂H₆+N₂ as film formation raw material was 0.015 nm/s. Meanwhile, an etching rate of a SiN film formed by LPCVD at 780° C. was 0.02 nm/s, and an etching rate of a SiO₂ film formed by thermal oxidation at 950° C. was 0.087 nm/s. From these results, although the SiN film obtained by using the method of the present invention by using SiCl₄+N₂ as film formation raw material was formed at 400° C., the SiN film was a highly dense film having an etching tolerance at the same level as that of the SiN film formed at 780° C. by LPCVD. Furthermore, the etching tolerance of a SiN film obtained by the method of the present invention was not significantly different from that of a SiN film obtained by using Si₂H₆+N₂ as film formation raw material, and the SiN film obtained by the method of the present invention exhibited significantly better etching tolerance as compared to a SiO₂ film formed by thermal oxidation. Accordingly, in the method of the present invention, increase of a thermal budget is remarkably suppressed compared to a conventional film formation method, while forming a dense and high quality SiN film.

As described above, in the method for forming a silicon nitride film of the present invention, a high quality silicon nitride film having concentration of hydrogen atoms below or equal to 9.9×10²⁰ atoms/cm³ in the silicon nitride film may be fabricated on the wafer W by performing plasma CVD by using a film formation gas including SiCl₄ gas and by selecting a ratio of a flow rate of SiCl₄ gas or N₂ gas and process pressure. A silicon nitride film with no hydrogen formed as described above may preferably be used for a purpose, for example, for a gate insulation film, a liner around a gate insulation film, an interlayer insulation film, a passivation film, an etching stopper film, etc., and, for such purposes, an effect of preventing deterioration of reliability due to hydrogen atoms may be expected.

The embodiments of the present invention have been described above, but the present invention is not limited to the above embodiments, and may vary.

### EXPLANATION OF REFERENCE NUMERALS

1: process chamber
2: holding stage
3: supporting member
5: heater
12: exhaust pipe
14, 15: gas introduction unit
16: transfer hole
17: gate valve
18: gas supply apparatus
19a: nitrogen gas supply source
19b: Si-containing gas supply source
19c: inert gas supply source
24: exhauster
27: microwave introduction apparatus
28: penetration plate
29: seal member
31: planar antenna
32: microwave radiation hole
37: waveguide
39: microwave generator
50: control unit
100: plasma CVD device
W: silicon wafer (substrate)

1. A silicon nitride film produced by a plasma CVD device which generates plasma by introducing microwaves into a process chamber by using a planar antenna having a plurality of apertures, by performing plasma CVD by using process gases including a gas of a compound composed of silicon atoms and chlorine atoms and a nitrogen gas, wherein concentration of hydrogen atoms in the silicon nitride film is below or equal to 9.9×10²⁰ atoms/cm³ in the silicon nitride film as measured by using secondary ion mass spectrometry (SIMS).

2. The silicon nitride film of claim 1, wherein no peak of N—H bonds is detected from the silicon nitride film by using a Fourier transform infrared spectroscopy (FT-IR).

3. A process for production of a silicon nitride film on an object to be processed by using a plasma CVD method by using a plasma CVD device which generates plasma by introducing microwaves into a process chamber by using a planar antenna having a plurality of apertures, the process comprising forming a silicon nitride film with a concentration of hydrogen atoms below or equal to 9.9×10²⁰ atoms/cm³ in the silicon nitride film as measured by using secondary ion mass spectrometry (SIMS) by setting a pressure inside the process chamber in a range from 0.1 Pa to 6.7 Pa and performing plasma CVD by using process gases including a gas of a compound composed of silicon atoms and chlorine atoms and a nitrogen gas.

4. The process of claim 3, wherein the compound composed of silicon atoms and chlorine atoms is tetrachlorosilane (SiCl₄).

5. The process of claim 4, wherein a flow rate ratio of the SiCl₄ gas to the entire process gases is in a range from 0.03% to 15%.

6. The process of claim 4, wherein a flow rate ratio of the nitrogen gas to the entire process gases is in a range from 5% to 99%.

7. A computer-readable storage medium having recorded thereon a control program to be operated on a computer, wherein the control program enables the computer to control a plasma CVD device that generates plasma by introducing microwaves into a process chamber by using a planar antenna having a plurality of apertures and performs film formation, to perform plasma CVD for forming a silicon nitride film with concentration of hydrogen atoms below or equal to 9.9×10²⁰ atoms/cm³ in the silicon nitride film as measured by using secondary ion mass spectrometry (SIMS), and by using process gases including a gas of compound composed of silicon atoms and chlorine atoms and a nitrogen gas and setting a pressure inside the process chamber in a range from 0.1 Pa to 6.7 Pa.

8. A plasma CVD device for production of a silicon nitride film on an object to be processed by using a plasma CVD method, the plasma CVD device comprising:
a process chamber which accommodates the object to be processed and has an opening on a top of the process chamber;
a dielectric member which closes the opening of the process chamber;
a planar antenna which is installed on the dielectric member and has a plurality of apertures for introducing microwaves into the process chamber and generating plasma;
a gas introduction unit which is connected to a gas supply apparatus for supplying process gases into the process chamber;
an exhauster which depressurizes and exhausts an inside of the process chamber; and
a control unit that controls plasma CVD to be performed to set a pressure inside the process chamber to be in a range from 0.1 Pa to 6.7 Pa and to produce the silicon nitride film having concentration of hydrogen atoms below or equal to 9.9×10²⁰ atoms/cm³ in the silicon nitride film as measured by using secondary ion mass spectrometry (SIMS), by using the process gases including a gas of a compound composed of silicon atoms and chlorine atoms and nitrogen gas from the gas introduction unit connected to the gas supply apparatus.
